(19) United States
(12) Patent Application Publication
(10) Pub. No.: US 2025/0293136 A1
(43) Pub. Date: Sep. 18, 2025

(54) BURIED BUMP STRUCTURE

(71) Applicant: QUALCOMM Incorporated, San Diego, CA (US)

(72) Inventors: Hong Bok WE, San Diego, CA (US); Joan Rey Villarba BUOT, Escondido, CA (US); Sang-Jae LEE, San Diego, CA (US); Zhijie WANG, San Diego, CA (US)

(21) Appl. No.: 18/607,094

(22) Filed: Mar. 15, 2024

(51) Int. Cl. H01L 23/498; H01L 21/48; H01L 23/00

(52) U.S. Cl. CPC H01L 23/49838; H01L 21/4853; H01L 24/16; H01L 23/49827; H01L 24/32; H01L 24/73; H01L 2224/16227; H01L 2224/16237; H01L 2224/32225; H01L 2224/73204

(57) ABSTRACT

In an aspect, an apparatus includes a die including a plurality of die connectors. The apparatus may include a package substrate including a first metallization structure disposed below the die, the first metallization structure includes: a plurality of dielectric layers, a plurality of metal layers disposed in the plurality of dielectric layers, a plurality of vias configured to couple adjacent metal layers of the plurality of metal layers through the plurality of dielectric layers; and a plurality of buried bump structures disposed in a top dielectric layer of the plurality of dielectric layers, wherein the plurality of buried bump structures is directly coupled to the plurality of die connectors.

### TECHNICAL FIELD

The present disclosure generally relates to semiconductor devices including an integrated circuit (IC) package, and more particularly, but not exclusively, to devices including a buried bump structure and fabrication techniques thereof.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips into an IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like. As used herein the term “function block” should not be construed to be power or signal lines, traces, conductors, pads, etc. that merely function to transmit an electrical voltage and/or current.

As designs become more complex, demands increase on the package substrate design. Conventional packaging substrate technology, such as Flip Chip Ball Grid Array (FCBGA) substrate technology use semi-additive process (SAP) with surface mount device (SMD) type Flip Chip (FC) pad connection. However, the conventional technology has limitations for fine bump pitch processing due to solder resist opening (SRO) and solder resist (SR) alignment process capability limitation.

Accordingly, there is a need for improved substrates or an IC package and methods of manufacturing the same to address the above-noted issues in the conventional technology and other improvements, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In some aspects, the apparatus comprises: a die including a plurality of die connectors; and a package substrate including a first metallization structure disposed below the die, the first metallization structure including: a plurality of dielectric layers; a plurality of metal layers disposed in the plurality of dielectric layers; a plurality of vias configured to couple adjacent metal layers of the plurality of metal layers through the plurality of dielectric layers; and a plurality of buried bump structures disposed in a top dielectric layer of the plurality of dielectric layers, wherein the plurality of buried bump structures is directly coupled to the plurality of die connectors.

In some aspects, the techniques described herein relate to a method of manufacturing an apparatus, the method comprising: providing a die including a plurality of die connectors; forming a package substrate including forming a first metallization structure, forming the first metallization structure including: forming a plurality of dielectric layers; forming a plurality of metal layers disposed in the plurality of dielectric layers; forming a plurality of vias coupling adjacent metal layers of the plurality of metal layers through the plurality of dielectric layers; and forming a plurality of buried bump structures disposed in a top dielectric layer of the plurality of dielectric layers; and directly coupling the plurality of buried bump structures to the plurality of die connectors.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B illustrate partial cross-sectional views of apparatus including an integrated circuit (IC) package, according to aspects of the disclosure.

FIGS. 2A-2P illustrate structures at various stages of manufacturing a substrate for an IC package, according to aspects of the disclosure.

FIGS. 3A and 3B illustrate structures at a final stage of manufacturing an IC package, according to aspects of the disclosure.

FIG. 3C illustrates a partial cross-sectional view of apparatus, according to aspects of the disclosure.

FIG. 4 illustrates a method for manufacturing a substrate for an IC package, according to aspects of the disclosure.

FIG. 5 illustrates a mobile device, according to aspects of the disclosure.

FIG. 6 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, substantially and the like indicate that the examples provided are not intended to be limited to the precise numerical values or geometric shapes and include normal variations due to, manufacturing tolerances and variations, material variations, and other design considerations. Further, relative terms such as “small”, “large”, “wide”, “fine”, “narrow”, “wide”, “thick”, “thin”, “high”, “low” and the like should be construed in the context of various design standards, technologies and/or applications. For example, fine line spacing may be construed based on minimum distances between lines for a given design standard and high voltage will depend on a given operating or standard voltage range for a given design. One skilled in the art will readily understand any of these terms used in the context of the disclosure provided herein.

As noted in the foregoing, conventional technologies including SR processing and resulting SRO formation results in limits on the reduction of bump spacing for die attachment. The various aspects disclosed provide improvements to reduce the pitch/distance between pads/bumps for die attachment to the package substrate, which can reduce the pitch in comparison to conventional designs. In some aspects, metal (e.g., copper (Cu)) pattern plating with an Ajinomoto build-up film (ABF) thinning process can be used to fabricate fine bump pitch with a similar structure to embedded trace substrate (ETS) processing, which is referred to herein as a “buried bump structure”. Conventional package substrates include a bump pitch of 110 micrometers (um). The various aspects disclosed herein allow for a bump pitch of approximately half of the conventional designs. For example, the buried bump structure can have a pitch of 64 micrometers (um) with a three-line escape pattern. In some aspects, the buried bump structure can have a reduction of the pitch to a pitch in the range of 40 um to 65 um with a 3-line escape configuration (e.g., 15 um bump+three 5 um traces and spacing). In addition to the bump pitch reduction, the various aspects disclosed protect escape line between bump with dielectric material, which prevents shorting failures. In contrast, in conventional designs and processing it is difficult to make escape line between bumps and to prevent shorting issues. Further, the various aspects disclosed prevent TC bump damage during assembly. Since the bumps are embedded in the dielectric material, the bumps are protected from mechanical damage during assembly. Still further, the various aspects eliminate the solder resist process, which simplifies the fabrication process and allows for an overall thickness reduction.

Additionally, the various aspects disclosed can prevent bump-on-lead (BOL) lifting during assembly due to fine pattern and BOL is buried under the ABF processing. Additionally, the various aspects disclosed allow for conventional assembly process infrastructure to be used. Additionally, the various aspects disclosed provide for the elimination of top SR processing on the package substrates (i.e., the package substrate does not have a to SR layer).

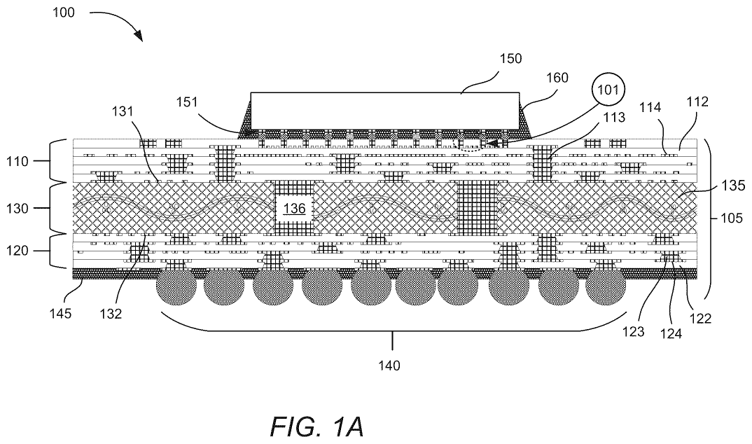

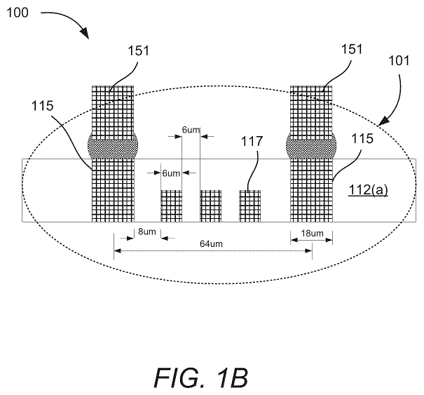

FIG. 1A is a cross-sectional view of an apparatus 100, according to aspects of the disclosure. In some aspects, FIG. 1A is a simplified cross-sectional view of the apparatus 100, and certain details and components of the apparatus 100 may be simplified or omitted in FIG. 1A. FIG. 1B is a cross-sectional view of an apparatus 100, according to aspects of the disclosure. In some aspects, FIG. 1B is an expanded cross-sectional view of portion 101 of the apparatus 100, and certain details and components of the apparatus 100 may be simplified or omitted in FIG. 1B.

In some aspects, as shown in FIG. 1A and FIG. 1B, the apparatus 100 is illustrated as a portion of an IC package and/or a larger apparatus such as a mobile phone, etc. In some aspects, the apparatus 100 includes a die 150 including a plurality of die connectors 151 and a package substrate 105. In some aspects, an underfill 160 is disposed between the die 150 and the package substrate 105 to provide mechanical bonding and encapsulate the connection of the die 150 to the package substrate 105 (e.g., die connectors 151 and buried bump structures 115). In some aspects, the die connectors 151 can be die bumps and solder balls, in other aspects the die connectors 151 may only be pins or pillars that are directly coupled to the package substrate 105. It will be appreciated that one or more dies may be coupled to the first metallization structure 110 and the various aspects disclosed and claimed are not limited to the illustrated examples.

In some aspects, the package substrate 105 includes a base substrate 130 having a first side and a second side. In some aspects, the base substrate 130 may comprise a core. A first metallization structure 110 is disposed on the first side of the base substrate 130. A second metallization structure 120 is disposed on the second side of the base substrate 130. In some aspects, the base substrate 130 may be coreless (e.g., designed as additional laminated layers or in some aspects the base substrate 130 may not be present in the coreless design). Further, in some aspects, the package substrate may be considered to have only one metallization structure included the buried bump structures as disclosed herein. Cored and coreless substrate designs are well known in the art and the various substrate design options will not be detailed and illustrated herein.

The first metallization structure 110 includes a plurality of dielectric layers 112, a plurality of metal layers 114 disposed in the plurality of dielectric layers 112 and a plurality of vias 113 coupling adjacent metal layers 114 of the plurality of metal layers 114 through the plurality of dielectric layers 112. The first metallization structure 110 further includes a plurality of buried bump structures 115 disposed in a top dielectric layer 112(a) of the plurality of dielectric layers 112, wherein the plurality of buried bump structures 115 is directly coupled to the plurality of die connectors 151. It will be appreciated that the buried bump structures 115 do not have solder resist openings in any solder resist (SR) layer as there is no SR layer deposited on the top dielectric layer 112(a) of the plurality of dielectric layers 112. Accordingly, the solder resist (SR) processing for the top of the package substrate 105 is not required in the disclosed aspects. In some aspects, a plurality of escape lines 117 (e.g., a three-line escape pattern as illustrated) may be disposed between adjacent buried bump structures 115. It will be appreciated that the various aspects disclosed and claimed are not limited to 3 lines and more or less lines (including no lines) may be present between the adjacent buried bump structures 115.

Additionally, as illustrated in FIG. 1B, in some aspects the pitch of the plurality of buried bump structures 115 is approximately 64 micrometers (um), which is substantially reduced in comparison to the conventional designs, as discussed above. In some aspects, the width of each of the buried bump structures 115 is approximately 18 micrometers (um). In some aspects, the width of each of the escape lines 117 is approximately 6 micrometers (um). In some aspects, the spacing between each of the escape lines 117 is approximately 6 micrometers (um) and the spacing between the buried bump structures 115 and an adjacent escape line 117 is approximately 8 micrometers (um). It will be appreciated that the various aspects disclosed and claimed are not limited to these specific numerical examples and each of the buried bump structures 115 and escape lines 117 may have different widths, pitch, and/or spacing.

Referring back to FIG. 1A, a second metallization structure 120 is disposed on the second side of the base substrate 130. The second metallization structure 120 includes a plurality of dielectric layers 122, a plurality of metal layers 124 disposed in the plurality of dielectric layers 122 and a plurality of vias 123 coupling adjacent metal layers 124 of the plurality of metal layers 124 through the plurality of dielectric layers 122. A connection structure 140 (e.g., solder balls, solder paste, copper pillars, etc.) is disposed on a bottom of the second metallization structure 120 opposite the base substrate 130 and is configured to electrically couple package substrate 105 through the second metallization structure 120 to external components, devices, etc. A solder resist layer 145 is disposed on the bottom of the second metallization structure 120 with the connection structure 140 being coupled to the second metallization structure 120 through solder resist openings (SROs) in the solder resist layer 145.

In some aspects, the base substrate 130 further includes a first metal layer 131 on the first side and a second metal layer 132 on the second side which are separated by a core 135. In some aspects, the core 135 may include a dielectric material with pre-impregnated reinforcement components embedded therein. In some aspects, the core 135 may include prepreg (also known as PPG), which may include polymer resins with fiber glass sheets impregnated therein. In some aspects, the base substrate 130 includes at least one plated through hole (PTH) 136 disposed through the core 135 configured to couple portions of the first metal layer 131 and the second metal layer 132 on opposite sides of the core 135.

In some aspects, the first metallization structure 110 may comprise multiple layers of Ajinomoto build-up film (ABF) or similar other epoxy or resin based layers. In some aspects, the second metallization structure may comprise fiberglass impregnated with resin (prepreg), Ajinomoto build-up film (ABF), a resin coated copper (RCC) build-up film or any similar material. In some aspects, the metal layers and vias of the first metallization structure 110, the second metallization structure 120 and base substrate 130 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

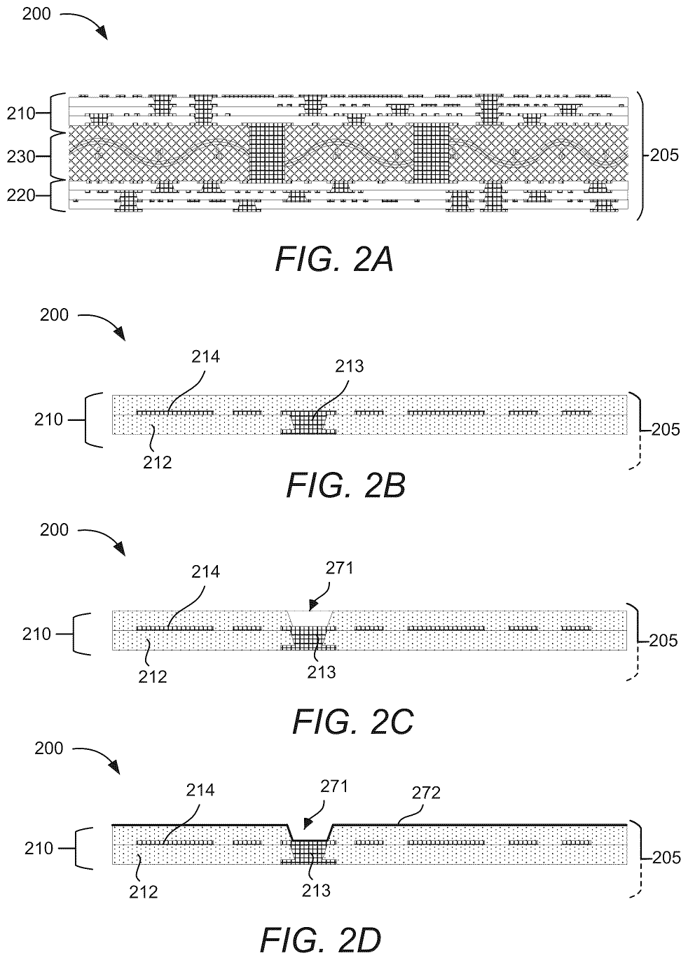

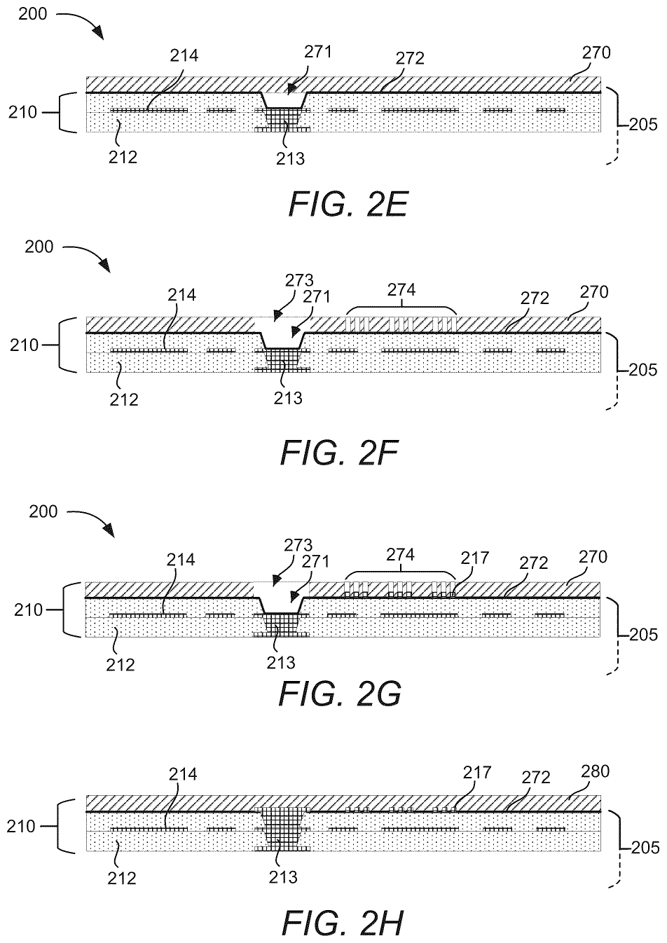

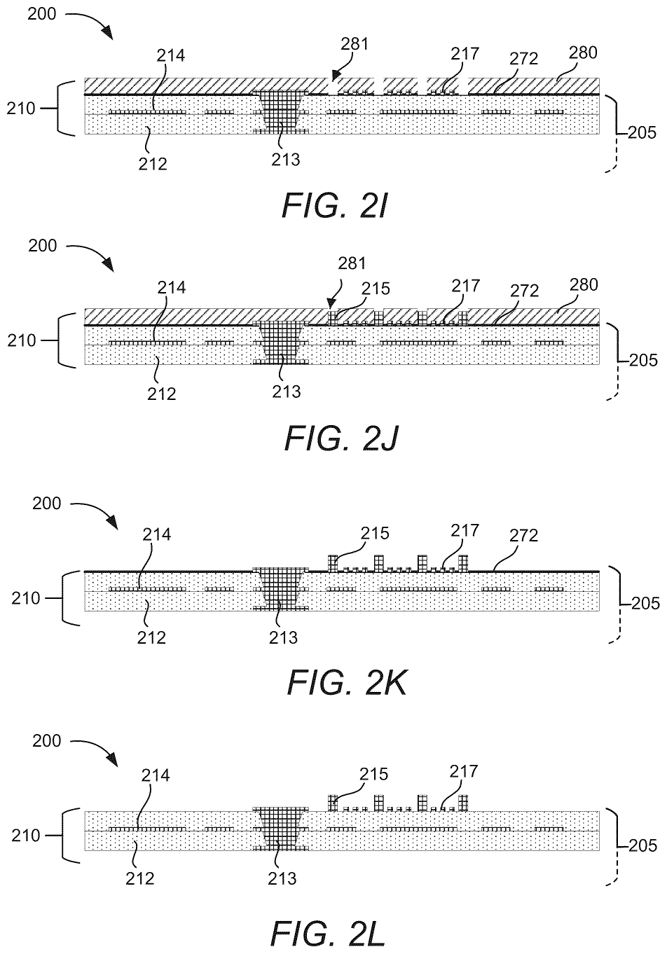

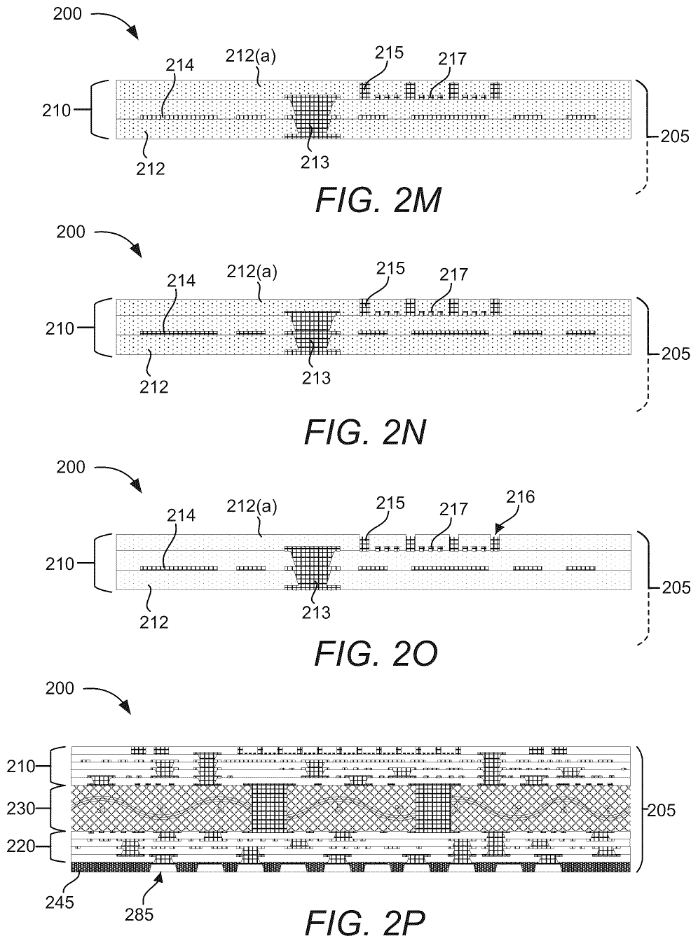

FIGS. 2A-2P illustrate structures at various stages of manufacturing/fabricating an apparatus 200, which is similar to the example apparatus 100 in FIG. 1A as a non-limiting example, according to aspects of the disclosure. Many of the elements illustrated in FIGS. 2A-2O are the same or similar to those of FIG. 1A, and therefore detailed description thereof may be omitted.

As shown in FIG. 2A, the fabrication process for apparatus 200 may begin with a package substrate 205 being partially formed including a first metallization structure 210, a second metallization structure 220 and base substrate 230, which are similar to corresponding elements described in the foregoing. The package substrate can be formed using conventional processes (build-up process) as noted above. To simplify the illustrations and eliminate unnecessary repetition, the following process stages will focus on the top layers of the first metallization structure 210.

In FIG. 2B, the fabrication process may continue with the first metallization structure 210 including a plurality of dielectric layers 212, a plurality of metal layers 214 disposed in the plurality of dielectric layers 212 and a plurality of vias 213 coupling adjacent metal layers 214 of the plurality of metal layers 214 through the plurality of dielectric layers 212.

In FIG. 2C, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214 and the plurality of vias 213. At this stage of the fabrication, the current top dielectric layer of the plurality of dielectric layers 212 has an opening 271 formed to pattern a via to couple and existing metal layer 214 to a metal layer to be formed in subsequent processing.

In FIG. 2D, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213 and opening 271. At this stage, a thick metal layer 272 is deposited over the exposed top portion of the package substrate 205 including the current top layer of the plurality of dielectric layers 212 and the opening 271. In some aspects, the thick metal layer 272 has a thickness in a range of 50% to 75% of the buried bump structure thickness.

In FIG. 2E, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, opening 271 and thick metal layer 272. At this stage, a dry film resist (DFR) layer 270 is deposited on the package substrate 205 over the thick metal layer 272.

In FIG. 2F, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, opening 271, thick metal layer 272 and DFR layer 270. At this stage, a second opening 273 is formed in the DFR layer 270 over the opening 271. Further, a plurality of fine openings 274 is formed in the DFR layer 270 and extend to the thick metal layer 272.

In FIG. 2G, the fabrication process for apparatus 200 may continue with the package substrate 205 being partially formed. The package substrate 205 including the first metallization structure 210, including the plurality of dielectric layers 212, the plurality of metal layers 214, the plurality of vias 213, opening 271, thick metal layer 272 and DFR layer 270. The DFR layer 270 includes the second opening 273 and plurality of fine openings 274. At this stage, a plurality of escape lines 217 (e.g., 3 groups of three-line escape patterns as illustrated) are formed in the bottom of the plurality of fine openings 274.

In FIG. 2H, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, thick metal layer 272 and the plurality of escape lines 217. At this stage, a second DFR layer 280 is deposited over the top surface of the package substrate 205. The second DFR layer 280 fills in the various openings and results in the plurality of escape lines 217 being covered.

In FIG. 2I, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, thick metal layer 272, the plurality of escape lines 217 and the second DFR layer 280. At this stage, a plurality of bump openings 281 are formed in the second DFR layer 280. The plurality of bump openings 281 extend to the thick metal layer 272 and are disposed adjacent to the three-line groups of the plurality of escape lines 217.

In FIG. 2J, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, thick metal layer 272, the plurality of escape lines 217 and the second DFR layer 280. At this stage, a plurality of buried bump structures 215 are formed in the plurality of the bump openings 281. It will be appreciated that the pitch of the plurality of bump openings 281 and the plurality of buried bump structures 215 corresponds to the pitch of the buried bump structures discussed in the foregoing, which is substantially smaller than the bump pad pitch in conventional designs. Further it will be appreciated that forming the escape lines 217 and the plurality of buried bump structures 215 may include multiple plating operations in the same layer. For example, a first thin plating for escape lines 217 may be performed and then the second plating in same layer may be performed to form thicker structures, in the same layer, such as the plurality of buried bump structures 215. Accordingly, forming the plurality of escape lines 217 may comprise plating a first metal portion of a first metal layer of the plurality of metal layers. Forming the plurality of buried bump structures 215 may comprise plating a second metal portion of a same metal layer and the first metal portion plated for the escape lines 217 is thinner than the second metal portion plated for the plurality of buried bump structures 215.

In FIG. 2K, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, thick metal layer 272, the plurality of escape lines 217 and the plurality of buried bump structures 215. At this stage, the second DFR layer 280 is removed from the package substrate 205 by a stripping process or any suitable process. With the second DFR layer 280 removed, the thick metal layer 272, the plurality of escape lines 217 and the plurality of buried bump structures 215 are exposed for further processing.

In FIG. 2L, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, the plurality of escape lines 217 and the plurality of buried bump structures 215. At this stage, the thick metal layer 272 is removed (e.g., etched) from the package substrate 205 leaving the plurality of escape lines 217 and the plurality of buried bump structures 215 exposed on the current top surface of the package substrate 205.

In FIG. 2M, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, the plurality of escape lines 217 and the plurality of buried bump structures 215. At this stage, a top dielectric layer 212(a) of the plurality of dielectric layers 212 is deposited on the package substrate 205 encapsulating the plurality of escape lines 217 and the plurality of buried bump structures 215.

In FIG. 2N, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, the plurality of escape lines 217, the plurality of buried bump structures 215 and the top dielectric layer 212(a). At this stage, the top dielectric layer 212(a) is ground down to expose the plurality of buried bump structures 215 while the plurality of escape lines 217 remain encapsulated in the top dielectric layer 212(a). It will be appreciated that, after the grinding is performed, the plurality of buried bump structures 215 is planar with the top surface of the top dielectric layer 212(a). In some aspects, the grinding is a panel level dielectric grind, which also allows for thickness control of the package substrate 205 and ultimately the apparatus 200. In some aspects, this portion of the fabrication process may stop at this stage with the plurality of buried bump structures 215 being planar with the top surface of the top dielectric layer 212(a). However, in other aspects, further processing may be performed.

In FIG. 2O, the fabrication process for apparatus 200 may continue with the package substrate 205 being partially formed. The package substrate 205 includes the first metallization structure 210. The first metallization structure 210 includes the plurality of dielectric layers 212, the plurality of metal layers 214, the plurality of vias 213, the plurality of escape lines 217, the plurality of buried bump structures 215 and the top dielectric layer 212(a). At this stage, which is optional and performed in some aspects, the plurality of buried bump structures 215 is partially etched (e.g., a soft etch process) to form a recess 216. Accordingly, the plurality of buried bump structures 215 is recessed from a top surface of the top dielectric layer 212(a) of the plurality of dielectric layers 212. It will be appreciated that, after this optional recessing process is performed, the plurality of buried bump structures 215 is no longer planar with the top surface of the top dielectric layer 212(a).

In FIG. 2P, the fabrication process for apparatus 200 may continue with the package substrate 205 being substantially formed. The package substrate 205 includes the first metallization structure 210, the base substrate 230 and the second metallization structure 220. At this stage, a solder resist (SR) layer 245 is deposited on the bottom of the second metallization structure 220. A plurality of solder resist openings (SROs) 285 is formed in the SR layer 245 to allow for the ball attach process in subsequent processing stages.

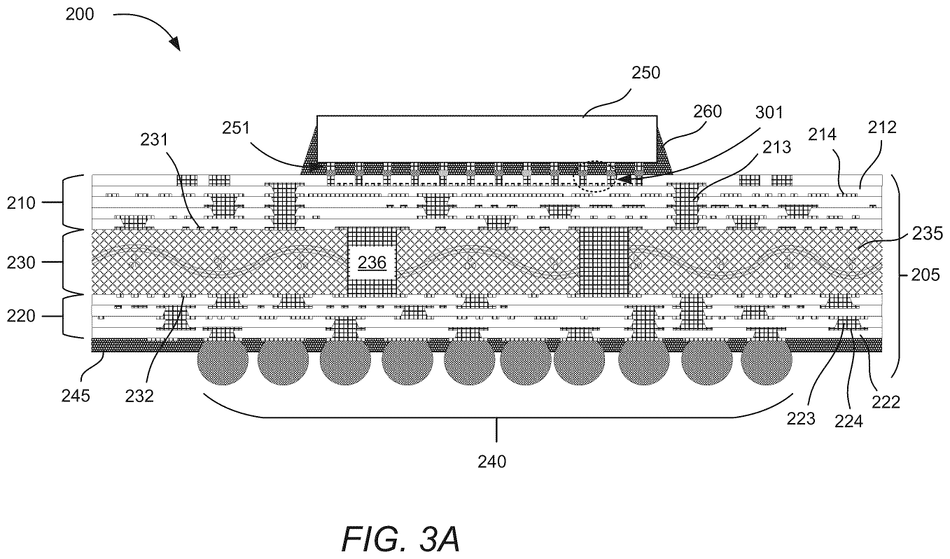

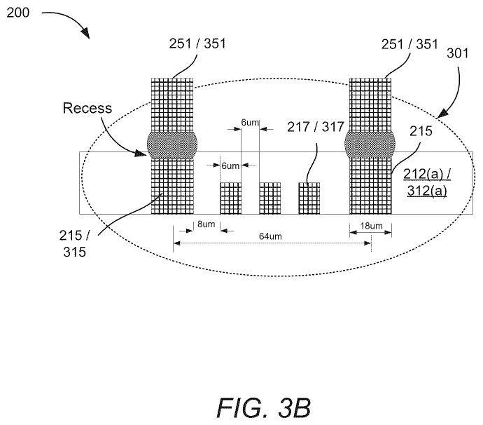

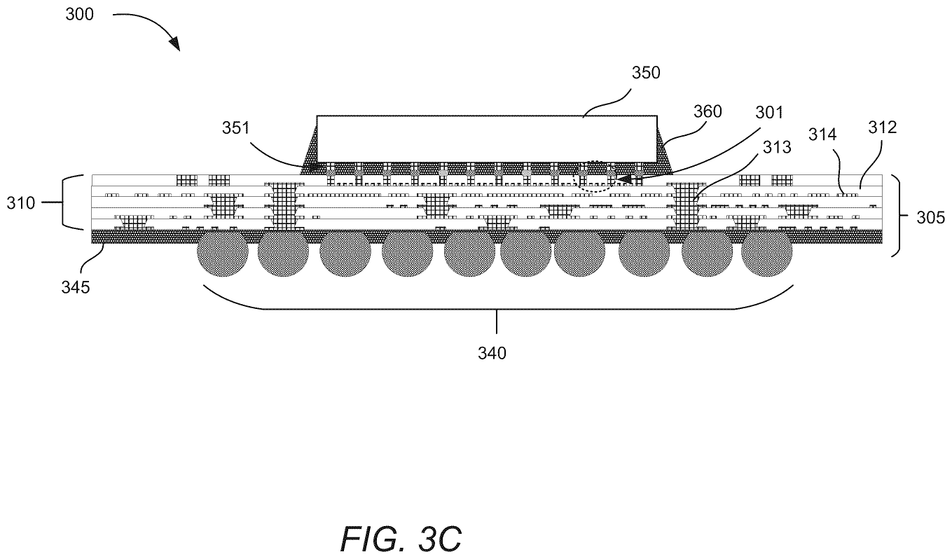

FIGS. 3A and 3B illustrate structures at the final stages of manufacturing/fabricating the apparatus 200. Additionally, the process stages are truncated to minimize redundant descriptions. Therefore, detailed description of elements and process stages may be omitted. For example, at this stage the ball attach process has been performed using conventional techniques. For example, in some aspects the ball attach process may be for a BGA of a Flip Chip Ball Grid Array (FCBGA) device. Additionally, a die 250 is coupled to the package substrate 205 using conventional process techniques (e.g., thermal compression bonding process). Further, an underfill 260 may be deposited between the die 250 and package substrate 205.

FIG. 3A is a cross-sectional view of the apparatus 200 at the final stage of processing, according to aspects of the disclosure. The various elements will be discussed for completeness, even if not expressly discussed in the example fabrication process. In some aspects, FIG. 3A is a simplified cross-sectional view of the apparatus 200, and certain details and components of the apparatus 200 may be simplified or omitted in FIG. 3A. FIG. 3B is a cross-sectional view of an apparatus 200, according to aspects of the disclosure. In some aspects, FIG. 3B is an expanded cross-sectional view of portion 301 of the apparatus 200, and certain details and components of the apparatus 200 may be simplified or omitted in FIG. 3B.

In some aspects, as shown in FIG. 3A and FIG. 3B, the apparatus 200 is illustrated as a portion of an IC package and/or a larger apparatus such as a mobile phone, etc. In some aspects, the apparatus 200 includes the die 250 including a plurality of die connectors 251 and the package substrate 205. In some aspects, the underfill 260 is disposed between the die 250 and the package substrate 205 to provide mechanical bonding and encapsulate the connection of the die 250 to the package substrate 205 (e.g., die connectors 251 and buried bump structures 215). In some aspects, the die connectors 251 can be die bumps and solder balls, in other aspects the die connectors 251 may only be pins or pillars that are directly coupled to the package substrate 205. It will be appreciated that one or more dies may be coupled to the first metallization structure 210 and the various aspects disclosed and claimed are not limited to the illustrated examples.

In some aspects, the package substrate 205 includes the base substrate 230 having a first side and a second side. In some aspects, the base substrate 230 may comprise a core and in other aspects the base substrate 230 may be coreless, as discussed above. The first metallization structure 210 includes a plurality of dielectric layers 212, a plurality of metal layers 214 disposed in the plurality of dielectric layers 212 and a plurality of vias 213 coupling adjacent metal layers 214 of the plurality of metal layers 214 through the plurality of dielectric layers 212. The first metallization structure 210 further includes a plurality of buried bump structures 215 disposed in a top dielectric layer 212(a) of the plurality of dielectric layers 212, wherein the plurality of buried bump structures 215 is directly coupled to the plurality of die connectors 251. It will be appreciated that the buried bump structures 215 do not have solder resist openings (SROs) in a solder resist (SR) layer as there is no SR layer deposited on the top dielectric layer 212(a) of the plurality of dielectric layers 212. Accordingly, the solder resist (SR) processing for the top of the package substrate 205 is not required in the disclosed aspects. In some aspects, the plurality of escape lines 217 (e.g., a three-line escape pattern as illustrated) may be disposed between adjacent buried bump structures 215. It will be appreciated that the various aspects disclosed and claimed are not limited to 3 lines and more or less lines (including no lines) may be present between the adjacent buried bump structures 215.

Additionally, as illustrated in FIG. 3B, in some aspects the pitch of the plurality of buried bump structures 215 is approximately 64 micrometers (um), which is substantially reduced in comparison to the conventional designs, as discussed above. In some aspects, the width of each of the buried bump structures 215 is approximately 18 micrometers (um). In some aspects, the width of each of the escape lines 217 is approximately 6 micrometers (um). In some aspects, the spacing between each of the escape lines 217 is approximately 6 micrometers (um) and the spacing between the buried bump structures 215 and an adjacent escape line 217 is approximately 8 micrometers (um). It will be appreciated that the various aspects disclosed and claimed are not limited to these specific numerical examples and each of the buried bump structures 215 and escape lines 217 may have different widths, pitch, and/or spacing. Further, as illustrated, the buried bump structures 215 are recessed from the top surface of the top dielectric layer 212(a), which corresponds to the recess process discussed in the foregoing in relation to FIG. 2O.

Referring back to FIG. 3A, a second metallization structure 220 is disposed on the second side of the base substrate 230. The second metallization structure 220 includes a plurality of dielectric layers 222, a plurality of metal layers 224 disposed in the plurality of dielectric layers 222 and a plurality of vias 223 coupling adjacent metal layers 224 of the plurality of metal layers 224 through the plurality of dielectric layers 222. A connection structure 240 (e.g., solder balls, BGA, solder paste, copper pillars, etc.) is disposed on a bottom of the second metallization structure 220 opposite the base substrate 230 and is configured to electrically couple the package substrate 205 through the second metallization structure 220 to external components, devices, etc. The solder resist layer 245 is disposed on the bottom of the second metallization structure 220 with the connection structure 240 being coupled to the second metallization structure 220 through solder resist openings (SROs) in the solder resist layer 245.

In some aspects, the base substrate 230 further includes a first metal layer 231 on the first side and a second metal layer 232 on the second side which are separated by a core 235. In some aspects, the core 235 may include a dielectric material with pre-impregnated reinforcement components embedded therein. In some aspects, the core 235 may include prepreg (also known as PPG), which may include polymer resins with fiber glass sheets impregnated therein. In some aspects, the base substrate 230 includes at least one plated through hole (PTH) 236 disposed through the core 235 configured to couple portions of the first metal layer 231 and the second metal layer 232 on opposite sides of the core 235.

In some aspects, the first metallization structure 210 may comprise multiple layers of Ajinomoto build-up film (ABF) or similar other epoxy or resin-based layers. In some aspects, the second metallization structure may comprise fiberglass impregnated with resin (prepreg), Ajinomoto build-up film (ABF), a resin coated copper (RCC) build-up film or any similar material. In some aspects, the metal layers and vias of the first metallization structure 210, the second metallization structure 220 and base substrate 230 may comprise any high conductive material, such as, copper (Cu), aluminum (AL), silver (Ag), gold (Au) titanium (Ti), nickel (Ni), tin (Sn), lead (Pb), alloys or combinations thereof.

FIG. 3C illustrates an apparatus 300 which is similar to apparatuses 100 and 200, except it is a coreless configuration. Accordingly, FIG. 3C is a simplified cross-sectional view of the apparatus 300, and certain details and components of the apparatus 300 may be simplified or omitted in FIG. 3C. Additionally, the connection details illustrated in FIG. 3B is also applicable to the coreless configuration.

In some aspects, as shown in FIG. 3C, the apparatus 300 is illustrated as a portion of an IC package and/or a larger apparatus such as a mobile phone, etc. In some aspects, the apparatus 300 includes the die 350 including a plurality of die connectors 351 and the package substrate 305. In some aspects, the underfill 360 is disposed between the die 350 and the package substrate 305 to provide mechanical bonding and encapsulate the connection of the die 350 to the package substrate 305 (e.g., die connectors 351 and buried bump structures 315). In some aspects, the die connectors 351 can be die bumps and solder balls, in other aspects the die connectors 351 may only be pins or pillars that are directly coupled to the package substrate 305. It will be appreciated that one or more dies may be coupled to the first metallization structure 310 and the various aspects disclosed and claimed are not limited to the illustrated examples.

In some aspects, the first metallization structure 310 includes a plurality of dielectric layers 312, a plurality of metal layers 314 disposed in the plurality of dielectric layers 312 and a plurality of vias 313 coupling adjacent metal layers 314 of the plurality of metal layers 314 through the plurality of dielectric layers 312. The first metallization structure 310 further includes a plurality of buried bump structures 315 disposed in a top dielectric layer 312(a) of the plurality of dielectric layers 312, wherein the plurality of buried bump structures 315 is directly coupled to the plurality of die connectors 351. It will be appreciated that the buried bump structures 315 do not have solder resist openings (SROs) in a solder resist (SR) layer as there is no SR layer deposited on the top dielectric layer 312(a) of the plurality of dielectric layers 312. Accordingly, the solder resist (SR) processing for the top of the package substrate 305 is not required in the disclosed aspects. In some aspects, the plurality of escape lines 317 (e.g., a three-line escape pattern as illustrated) may be disposed between adjacent buried bump structures 315. It will be appreciated that the various aspects disclosed and claimed are not limited to 3 lines and more or less lines (including no lines) may be present between the adjacent buried bump structures 315.

A connection structure 340 (e.g., solder balls, BGA, solder paste, copper pillars, etc.) is disposed on a bottom of the first metallization structure 310 opposite the die 350 and is configured to electrically couple the package substrate 305 through the first metallization structure 310 to external components, devices, etc. The solder resist layer 345 is disposed on the bottom of the first metallization structure 310 with the connection structure 340 being coupled to the first metallization structure 310 through solder resist openings (SROs) in the solder resist layer 345.

In some aspects, the first metallization structure 310 may comprise multiple layers of Ajinomoto build-up film (ABF) or similar other epoxy or resin based layers. In some aspects, the metal layers and vias of the first metallization structure 310 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

It will be appreciated that additional processing can be performed using known techniques to form and attach additional structures (e.g., a mold compound, lid, etc. may be used to encapsulate the die/package substrate). Additional dies may be coupled to the package substrate directly or arranged in a stacked structure. Further, the various aspects disclosed may include additional substrates that may be used to interface to a printed circuit board (PCB) or other external device. Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

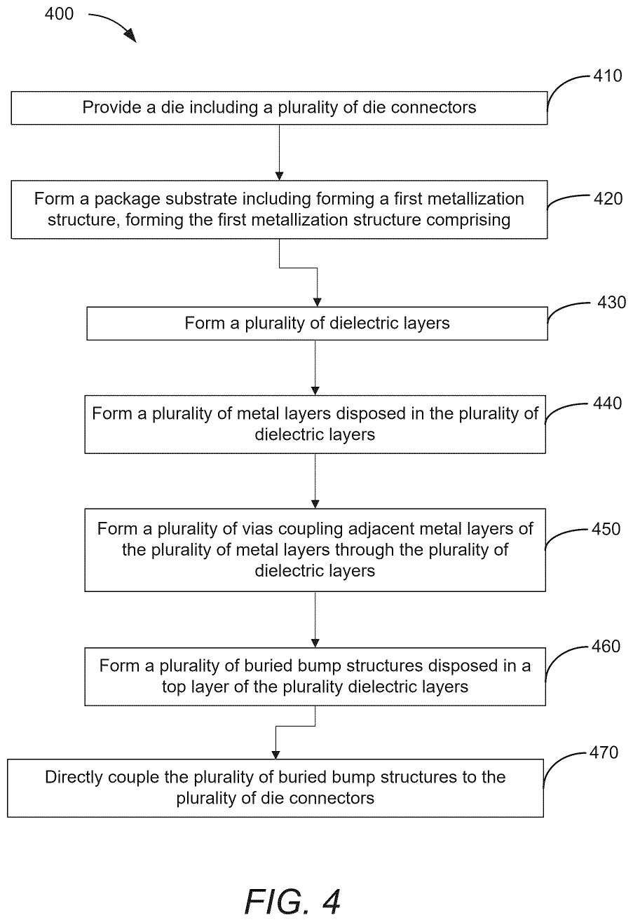

FIG. 4 illustrates a method 400 for manufacturing/fabricating an apparatus with buried bump structures (such as a substrate for an IC package incorporating the features of any of the example apparatuses 100, 200 and/or 300), according to aspects of the disclosure. In some aspects, FIGS. 2A-2P may depict the substrate at different stages of manufacturing according to the method 400. It will be appreciated from the foregoing that there are various methods for fabricating devices including a plurality of buried bump structures as disclosed herein.

At operation 410, the process includes providing a die (e.g., die 150 or 250) including a plurality of die connectors (e.g., die connectors 151 or 251).

At operation 420, the process includes forming a package substrate (e.g., package substrate 105 or 205) including forming a first metallization structure (e.g., first metallization structure 110 or 210).

At operation 430, the process for forming the first metallization structure (e.g., first metallization structure 110 or 210) includes forming a plurality of dielectric layers (e.g., dielectric layers 112 or 212).

At operation 440, the process for forming the first metallization structure (e.g., first metallization structure 110 or 210) includes forming a plurality of metal layers (e.g., metal layers 114 or 214) disposed in the plurality of dielectric layers (e.g., dielectric layers 112 or 212).

At operation 450, the process for forming the first metallization structure (e.g., first metallization structure 110 or 210) includes forming a plurality of vias (e.g., vias 113 or 213) coupling adjacent metal layers of the plurality of metal layers (e.g., metal layers 114 or 214) through the plurality of dielectric layers (e.g., dielectric layers 112 or 212).

At operation 460, the process for forming the first metallization structure (e.g., first metallization structure 110 or 210) includes forming a plurality of buried bump structures (e.g., buried bump structures 115 or 215) disposed in a top dielectric layer (e.g., top dielectric layer 112(a) or 212(a)) of the plurality of dielectric layers (e.g., dielectric layers 112 or 212).

At operation 470, the process includes providing a die (e.g., die 150 or 250) including directly coupling the plurality of buried bump structures (e.g., buried bump structures 115 or 215) to the plurality of die connectors (e.g., die connectors 151 or 251).

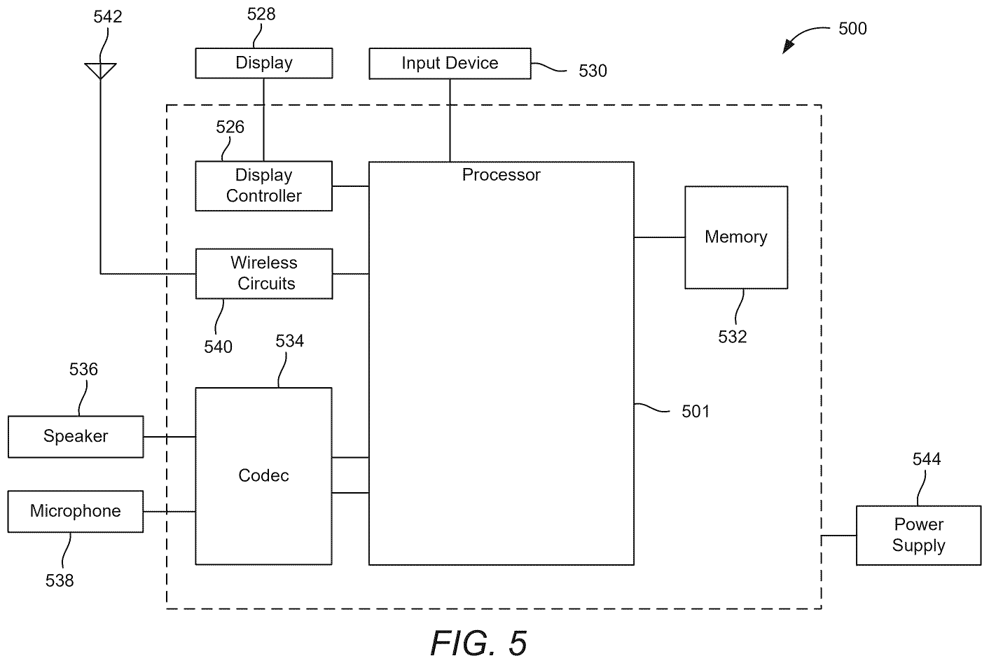

FIG. 5 illustrates a mobile device 500, according to aspects of the disclosure. In some aspects, the mobile device 500 may be implemented by including one or more IC devices including the buried bump structures as disclosed herein.

In some aspects, mobile device 500 may be configured as a wireless communication device. As shown, mobile device 500 includes processor 501. Processor 501 may be communicatively coupled to memory 532 over a link, which may be a die-to-die or chip-to-chip link. Mobile device 500 also includes display 528 and display controller 526, with display controller 526 coupled to processor 501 and to display 528. The mobile device 500 may include input device 530 (e.g., physical, or virtual keyboard), power supply 544 (e.g., battery), speaker 536, microphone 538, and wireless antenna 542. In some aspects, the power supply 544 may directly or indirectly provide the supply voltage for operating some or all of the components of the mobile device 500.

In some aspects, FIG. 5 may include coder/decoder (CODEC) 534 (e.g., an audio and/or voice CODEC) coupled to processor 501; speaker 536 and microphone 538 coupled to CODEC 534; and wireless circuits 540 (which may include a modem, RF circuitry, filters, etc.) coupled to wireless antenna 542 and to processor 501.

In some aspects, one or more of processor 501 (e.g., SoCs, application processor (AP), central processing unit (CPU), digital signal processor (DSP), etc.), display controller 526, memory 532, CODEC 534, and wireless circuits 540 (e.g., baseband interface) including IC devices that are packaged as IC packages and including buried bump structures according to the various aspects described in this disclosure.

It should be noted that although FIG. 5 depicts a mobile device 500, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

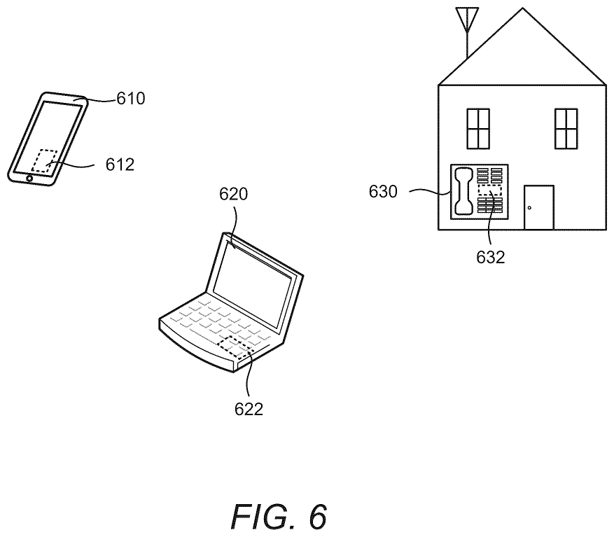

FIG. 6 illustrates various electronic devices 610, 620, and 630 that may incorporate IC devices 612, 622, and 632, which may be packaged as IC packages having buried bump structures as disclosed herein, according to aspects of the disclosure.

For example, a mobile phone device 610, a laptop computer device 620, and a fixed location terminal device 630 may each be considered generally user equipment (UE) and may include one or more IC devices, such as IC devices 612, 622, and 632, and a power supply to provide the supply voltages to power the IC devices. The IC devices 612, 622, and 632 may, for example, correspond to an IC device package having buried bump structures as described herein.

The devices 610, 620, and 630 illustrated in FIG. 6 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1A-6 may be rearranged and/or combined into a single component, process, feature, or function or incorporated in several components, processes, or functions. Additional elements, components, processes, and/or functions may also be added without departing from the disclosure. In some implementations, FIGS. 1A-6 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising: a die including a plurality of die connectors; and a package substrate including a first metallization structure disposed below the die, the first metallization structure comprising: a plurality of dielectric layers; a plurality of metal layers disposed in the plurality of dielectric layers; a plurality of vias configured to couple adjacent metal layers of the plurality of metal layers through the plurality of dielectric layers; and a plurality of buried bump structures disposed in a top dielectric layer of the plurality of dielectric layers, wherein the plurality of buried bump structures is directly coupled to the plurality of die connectors.

Clause 2. The apparatus of clause 1, wherein the plurality of buried bump structures is planar with a top surface of the top dielectric layer of the plurality of dielectric layers.

Clause 3. The apparatus of any of clauses 1 to 2, the plurality of buried bump structures is recessed from a top surface of the top dielectric layer of the plurality of dielectric layers.

Clause 4. The apparatus of any of clauses 1 to 3, wherein the first metallization structure comprises: a plurality of escape lines disposed between adjacent buried bump structures of the plurality of buried bump structures.

Clause 5. The apparatus of clause 4, wherein at least a portion of the plurality of escape lines is configured in a three-line escape pattern.

Clause 6. The apparatus of clause 5, wherein a spacing between one of the adjacent buried bump structures and an adjacent escape line is approximately 8 micrometers.

Clause 7. The apparatus of clause 6, wherein a width of each of the plurality of escape lines is approximately 6 micrometers.

Clause 8. The apparatus of any of clauses 1 to 7, wherein the first metallization structure comprises Ajinomoto build-up film (ABF).

Clause 9. The apparatus of any of clauses 1 to 8, wherein the package substrate further comprises: a base substrate comprising a core including pre-impregnated reinforcement components embedded therein.

Clause 10. The apparatus of clause 9, wherein the base substrate comprises: at least one plated through hole (PTH) disposed through the core configured to couple portions of metal layers on opposite sides of the core.

Clause 11. The apparatus of any of clauses 9 to 10, wherein the package substrate further comprises: a second metallization structure comprising a plurality of dielectric layers, a plurality of metal layers and a plurality of vias, and wherein the first metallization structure is disposed on a first side of the base substrate opposite the die and the second metallization structure is disposed on a second side of the base substrate opposite the first metallization structure.

Clause 12. The apparatus of clause 11, wherein the second metallization structure comprises: fiberglass impregnated with resin (prepreg), Ajinomoto build-up film (ABF), or a resin coated copper (RCC) build-up film.

Clause 13. The apparatus of any of clauses 1 to 12, wherein a pitch of the plurality of buried bump structures is approximately 64 micrometers.

Clause 14. The apparatus of any of clauses 1 to 13, wherein a width of each of the plurality of buried bump structures is approximately 18 micrometers.

Clause 15. The apparatus of any of clauses 1 to 14, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Clause 16. A method of manufacturing an apparatus, the method comprising: providing a die including a plurality of die connectors; forming a package substrate including forming a first metallization structure, forming the first metallization structure comprising: forming a plurality of dielectric layers; forming a plurality of metal layers disposed in the plurality of dielectric layers; forming a plurality of vias coupling adjacent metal layers of the plurality of metal layers through the plurality of dielectric layers; and forming a plurality of buried bump structures disposed in a top dielectric layer of the plurality of dielectric layers; and directly coupling the plurality of buried bump structures to the plurality of die connectors.

Clause 17. The method of clause 16, further comprising: grinding a top surface of the top dielectric layer until the plurality of buried bump structures is planar with the top surface of the top dielectric layer.

Clause 18. The method of clause 17, further comprising: etching the plurality of buried bump structures to recess the plurality of buried bump structures from the top surface of the top dielectric layer.

Clause 19. The method of any of clauses 16 to 18, further comprising: forming a plurality of escape lines disposed between adjacent buried bump structures of the plurality of buried bump structures.

Clause 20. The method of clause 19, wherein forming the plurality of escape lines comprises plating a first metal portion of a first metal layer of the plurality of metal layers, and wherein forming the plurality of buried bump structures comprises plating a second metal portion of the first metal layer, wherein the first metal portion is thinner than the second metal portion.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus, comprising:
a die including a plurality of die connectors; and
a package substrate including a first metallization structure disposed below the die, the first metallization structure comprising:
a plurality of dielectric layers;
a plurality of metal layers disposed in the plurality of dielectric layers;
a plurality of vias configured to couple adjacent metal layers of the plurality of metal layers through the plurality of dielectric layers; and
a plurality of buried bump structures disposed in a top dielectric layer of the plurality of dielectric layers, wherein the plurality of buried bump structures is directly coupled to the plurality of die connectors.

2. The apparatus of claim 1, wherein the plurality of buried bump structures is planar with a top surface of the top dielectric layer of the plurality of dielectric layers.

3. The apparatus of claim 1, wherein the plurality of buried bump structures is recessed from a top surface of the top dielectric layer of the plurality of dielectric layers.

4. The apparatus of claim 1, wherein the first metallization structure comprises:
a plurality of escape lines disposed between adjacent buried bump structures of the plurality of buried bump structures.

5. The apparatus of claim 4, wherein at least a portion of the plurality of escape lines is configured in a three-line escape pattern.

6. The apparatus of claim 5, wherein a spacing between one of the adjacent buried bump structures and an adjacent escape line is approximately 8 micrometers.

7. The apparatus of claim 6, wherein a width of each of the plurality of escape lines is approximately 6 micrometers.

8. The apparatus of claim 1, wherein the first metallization structure comprises Ajinomoto build-up film (ABF).

9. The apparatus of claim 1, wherein the package substrate further comprises:
a base substrate comprising a core including pre-impregnated reinforcement components embedded therein.

10. The apparatus of claim 9, wherein the base substrate comprises:
at least one plated through hole (PTH) disposed through the core configured to couple portions of metal layers on opposite sides of the core.

11. The apparatus of claim 9, wherein the package substrate further comprises:
a second metallization structure comprising a plurality of dielectric layers, a plurality of metal layers and a plurality of vias, and
wherein the first metallization structure is disposed on a first side of the base substrate opposite the die and the second metallization structure is disposed on a second side of the base substrate opposite the first metallization structure.

12. The apparatus of claim 11, wherein the second metallization structure comprises:
fiberglass impregnated with resin (prepreg), Ajinomoto build-up film (ABF), or a resin coated copper (RCC) build-up film.

13. The apparatus of claim 1, wherein a pitch of the plurality of buried bump structures is approximately 64 micrometers.

14. The apparatus of claim 1, wherein a width of each of the plurality of buried bump structures is approximately 18 micrometers.

15. The apparatus of claim 1, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

16. A method of manufacturing an apparatus, the method comprising:
providing a die including a plurality of die connectors;
forming a package substrate including forming a first metallization structure, forming the first metallization structure comprising:
forming a plurality of dielectric layers;
forming a plurality of metal layers disposed in the plurality of dielectric layers;
forming a plurality of vias coupling adjacent metal layers of the plurality of metal layers through the plurality of dielectric layers; and
forming a plurality of buried bump structures disposed in a top dielectric layer of the plurality of dielectric layers; and
directly coupling the plurality of buried bump structures to the plurality of die connectors.

17. The method of claim 16, further comprising:
grinding a top surface of the top dielectric layer until the plurality of buried bump structures is planar with the top surface of the top dielectric layer.

18. The method of claim 17, further comprising:
etching the plurality of buried bump structures to recess the plurality of buried bump structures from the top surface of the top dielectric layer.

19. The method of claim 16, further comprising:
forming a plurality of escape lines disposed between adjacent buried bump structures of the plurality of buried bump structures.

20. The method of claim 19,
wherein forming the plurality of escape lines comprises plating a first metal portion of a first metal layer of the plurality of metal layers, and
wherein forming the plurality of buried bump structures comprises plating a second metal portion of the first metal layer, wherein the first metal portion is thinner than the second metal portion.
